(19) United States
(12) Patent Application Publication
(10) Pub. No.: US 2005/0048732 A1
(43) Pub. Date: Mar. 3, 2005

(54) METHOD TO PRODUCE TRANSISTOR HAVING REDUCED GATE HEIGHT

(75) Inventors: Heemyoung Park, La Grangeville, NY (US); Paul D. Agnello, Wappingers Falls, NY (US); Percy V. Gilbert, Poughquag, NY (US); Byoung H. Lee, Wappingers Falls, NY (US); Patricia A. O'Neil, Newburgh, NY (US); Ghavam G. Shahidi, Yorktown Heights, NY (US); Jeffrey J. Welser, Amawalk, NY (US)

Correspondence Address: FREDERICK W. GIBB, III;MCGINN & GIBB, PLLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 10/604,912

(22) Filed: Aug. 26, 2003

(51) Int. Cl. H01L 21/336

(52) U.S. Cl. 438/305

(57) ABSTRACT

Disclosed is a method and system of forming an integrated circuit transistor having a reduced gate height that forms a laminated structure having a substrate, a gate conductor above the substrate, and at least one sacrificial layer above the gate conductor. The process patterns the laminated structure into at least one gate stack extending from the substrate, forms spacers adjacent to the gate stack, dopes regions of the substrate not protected by the spacers to form source and drain regions adjacent the gate stack, and removes the spacers and the sacrificial layer.

### BACKGROUND OF INVENTION

The present invention generally relates to integrated circuit transistors and more particularly to an improved structure and method that reduces the height of the gate electrode and simultaneously confines active dopants within each electrode, thereby maximizing integrated circuit performance.

Challenges are encountered during conventional processing of high-performance complementary metal oxide semiconductor (CMOS) devices. As the feature size of transistors is scaled down, it is not only the size of electrodes (source, drain, and gate), but also the distance between them that becomes smaller, as they are formed closer to each other. The closer proximity increases electric field between the electrodes during operation of the device. For the overall integrated circuit performance, therefore, it becomes more and more critical to minimize parasitic capacitance between the electrodes, and at the same time, to maximize the drive currents without increasing the off-state leakage of the devices.

The height of gate poly stack affects parasitic capacitance between the gate and the source and drain (S/D) contact structures and their electrical extensions such as extension doping overlap with gate and metallization contacts. The reduction of poly height i.e. the smaller sidewall area of the poly gate lines decreases the peripheral components of outer-fringe capacitance between the gate poly line and the source/drain electrodes and their associated contact structures. The gate-to-source/drain extension capacitances substantially affects the overall speed of the integrated circuits for logic applications in addition to the current drivability and power. Therefore, it is desirable to reduce the height of the gate.

Conventional CMOS processing with self-aligned source/drain/gate implantation limits the amount by which the gate height can be reduced. Implanting dopants with a sufficient energy to dope the source and drain regions and for halo formation using the poly gate as a self-aligned mask can cause the dopants to penetrate through the poly gate and the gate dielectric into the channel as the gate height is decreased. Therefore, as the gate height is decreased, the risk of gate impurity contaminating the underlying gate oxide increases. To avoid this, some conventional processes reduce the total thermal budget of the manufacturing process. However, reducing the overall thermal budget can lead to insufficient dopant activation in other electrodes and as a result, drive currents may be limited. Alternatively, the self-aligned gate/source/drain and halo implant energy may be drastically reduced to mitigate the dopant penetration; however, the low energy implants for the source/drain and the halo cause high source/drain parasitic resistance and insufficient halo doping in the channel, degrading drive currents and short-channel rolloff characteristics.

In addition, the maximum sidewall spacer length achievable with a gate of reduced height—poses challenges. With the shorter gate height, the maximum size of the spacer is reduced due to the reduced step height for the RIE (reactive ion etch) of a deposited spacer material of a given thickness, resulting in lateral encroachment of S/D dopants, and a higher probability of silicide bridging between the gate and the S/D. This problem becomes more severe when using epitaxially grown raised source and drain structures because epitaxial overgrowth occurs on top of the gate with reduced height. The undesirably overgrown epitaxial polysilicon over the gate would also be silicided which would form a conductive path between the gate and the raised source and drain regions, resulting in failure of transistor function.

Besides the problems discussed above with respect to shortening the height of the gate, conventional CMOS processing with RSD (raised source/drain) also suffers from unnecessary transient enhanced diffusion (TED). More specifically impurities, such as boron, can diffuse into the channel from halo implants for N-type field effect transistor (NFET), from extension and source/drain implants for P-type field effect transistor (PFET) during RSD processing. More specifically, the silicon selective epitaxial process to build RSD on thin SOI structures is normally performed at temperatures around 700C to 900C for an extended thermal cycles more than several minutes. This thermal condition is typically known to cause the most significant TED of major dopants, particularly boron, causing detrimental effects on short channel devices such as increased roll off of threshold voltage.

### SUMMARY OF INVENTION

The invention provides a method to form an integrated circuit transistor having a reduced gate height. The invention provides a methodology of forming a laminated structure having a substrate, a gate conductor above the substrate, and at least one sacrificial layer above the gate conductor. The invention patterns the laminated structure into at least one gate stack extending from the substrate by forming spacers adjacent the gate stack and forms doping regions of the substrate not protected by the spacers to form the source and drain regions adjacent the gate stack. The invention then removes the spacers and the sacrificial layer.

The height of the gate conductor is smaller than a gate height associated with the spacing of the source and drain regions created by the spacers. The size of the spacers is controlled by the combined height of the gate conductor and the sacrificial layer, such that the spacers provide larger spacing for the combined height when compared to the height of the gate conductor alone. The larger spacing positions the source and drain regions further from the gate conductor when compared to source and drain regions formed with spacers formed only to the height of the gate conductor.

The sacrificial layer above the gate conductor is formed by forming a sacrificial oxide layer above the gate conductor and forming additional sacrificial layers above the oxide layer. The sacrificial oxide layer protects the gate conductor. The laminated structure has a silicon layer below the gate conductor and further dopes source/drain electrodes and the gate conductor together in a self-aligned implantation after the patterning process.

The combined height of the gate conductor and the sacrificial layer prevents the impurity from reaching the silicon layer and without the sacrificial layer the doping process would implant an impurity through the gate conductor and gate dielectric layer to the silicon layer. The laminated structure has a silicon layer below the gate conductor. The source/drain electrodes and the gate conductor are doped together in a self-aligned implantation after the patterning process. The invention also provides a second doping process of doping halo regions below the gate conductor in a self-aligned implantation with an impurity of an opposite polarity to that used in the first doping process. The combined height of the gate conductor and the sacrificial layer prevents impurities from reaching the silicon layer, and without the sacrificial layer, the doping processes would implant impurities through the gate conductor and gate dielectric layer to the silicon layer.

The invention further provides a method of epitaxially growing raised source and drain regions above the substrate layer adjacent the temporary spacers, such that the temporary spacers separate the raised source and drain regions from the gate stack. Then the invention grows an additional dielectric layer on the raised source and drain regions, removes the temporary spacers without removing the sacrificial material, performs a halo implant in the raised source and drain regions and in exposed regions of the silicon layer and forms a permanent spacer adjacent the gate stack. The permanent spacer is thinner than the temporary spacer. Next, the invention implants impurities into the raised source and drain regions and exposed regions of the silicon, forms a final spacer filling the exposed regions of the silicon between the permanent spacer and the raised source and drain regions. This is followed by implanting additional impurities into the raised source and drain regions and exposed regions of the silicon, annealing to activate all impurities, etching back the additional dielectric layer on the raised source and drain regions, and saliciding both the gate conductor and the raised source and drain regions.

The artificial increase in gate height achieved with the sacrificial layer at the top of the gate stack allows the formation of larger disposable spacers. The invention uses a two-step spacer formation process for spacer width modulation (sacrificial and permanent spacers). With the larger spacers, the invention also avoids the dopant encroachment and silicide bridging problems that can occur when the reduced gate height limits and decreases the achievable size of the spacers.

### BRIEF DESCRIPTION OF DRAWINGS

The invention will be better understood from the following detailed description of preferred embodiments with reference to the drawings, in which:

FIGS. 1A and 1B are schematic diagrams of partially completed N-type and P-type transistors;

FIGS. 2A and 2B are schematic diagrams of partially completed N-type and P-type transistors;

FIGS. 3A and 3B are schematic diagrams of partially completed N-type and P-type transistors;

FIGS. 4A and 4B are schematic diagrams of partially completed N-type and P-type transistors;

FIGS. 5A and 5B are schematic diagrams of partially completed N-type and P-type transistors;

FIGS. 6A and 6B are schematic diagrams of partially completed N-type and P-type transistors;

FIGS. 7A and 7B are schematic diagrams of partially completed N-type and P-type transistors;

FIGS. 8A and 8B are schematic diagrams of partially completed N-type and P-type transistors;

FIGS. 9A and 9B are schematic diagrams of partially completed N-type and P-type transistors;

FIGS. 10A and 10B are schematic diagrams of partially completed N-type and P-type transistors;

FIGS. 11A and 11B are schematic diagrams of partially completed N-type and P-type transistors;

FIGS. 12A and 12B are schematic diagrams of partially completed N-type and P-type transistors;

FIGS. 13A and 13B are schematic diagrams of partially completed N-type and P-type transistors;

FIGS. 14A and 14B are schematic diagrams of partially completed N-type and P-type transistors; and

FIGS. 15A and 15B are schematic diagrams of partially completed N-type and P-type transistors.

### DETAILED DESCRIPTION

The invention presents a novel method of scaling down dimensions of all the electrodes in CMOS devices on SOI, including gate height. The invention resolves the problems associated with gate height reduction by providing a sacrificial layer above the gate poly. The buffer layer on top of the gate polysilicon artificially increases the gate height during the subsequent process integration, thereby making it possible to perform source, drain, and halo implantation at an energy high enough to sufficiently dope the source/drain and channel regions without incurring the problem of boron penetration through the poly gate and gate dielectric layer (as discussed above). In other words, the conventional self-aligned implantation process can be utilized with the invention because the thickness of the buffer layer causes the impurities to be implanted to the same depth within the inventive device structure including the source/drain and halo junctions and sidewall spacer size, as they would be with conventional taller gate structures.

The artificial increase in gate height achieved with the sacrificial layer at the top of the gate stack allows the formation of larger disposable spacers. The invention uses a two-step spacer formation process for spacer width modulation (sacrificial and permanent spacers). With the larger spacers, the invention also avoids the dopant encroachment and silicide bridging problems that can occur when the reduced gate height limits and decreases the achievable size of the spacers (as discussed above).

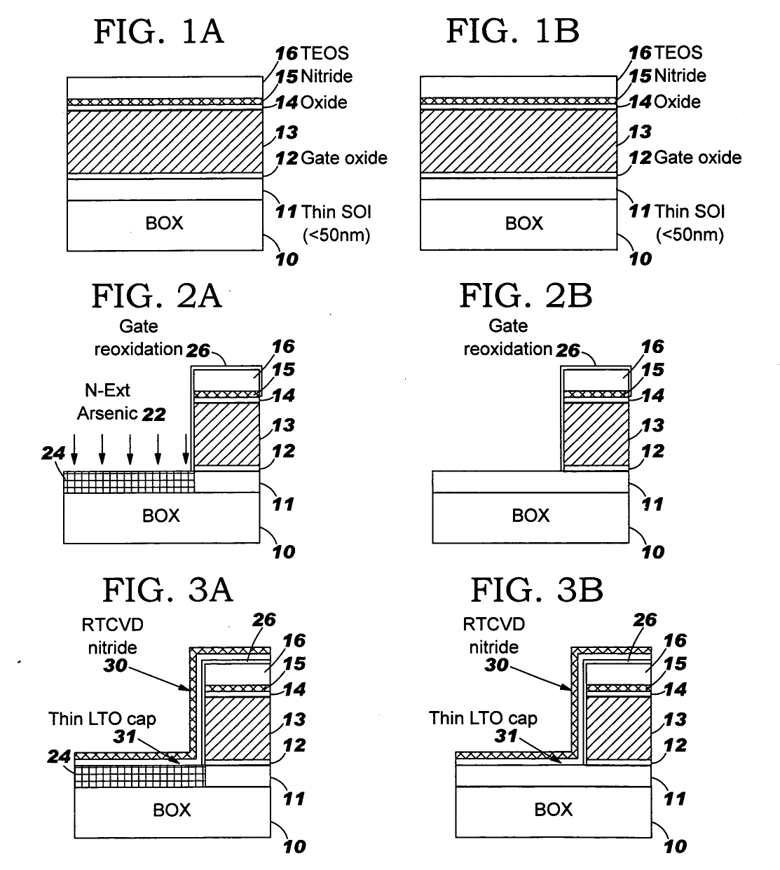

To avoid the boron diffusion problem discussed above, the invention implants boron for N-halo, P-extension and P-type source and drains after the raised source/drains are formed. This process still allows slow diffusing dopants, such as arsenic, to be introduced before the RSD processing. Additionally, the width of the spacer is made relatively larger for PFET boron/BF2 source/drain implants than for NFET arsenic implant, in order to give more room for boron diffusion in the PFET sources and drains. The invention decouples NFET and PFET dopant species. More specifically, the invention decouples boron implantation using the large disposable spacers to minimize any effects of lateral encroachment of boron during the RSD selective epitaxial process. FIGS. 1A-15B illustrate one example of the invention, shown in schematic cross-section. The invention is not limited to these examples, but instead is equally applicable to all similar structures. These examples have been selected as representative of the invention; however, the invention is not limited explicitly only to these examples.

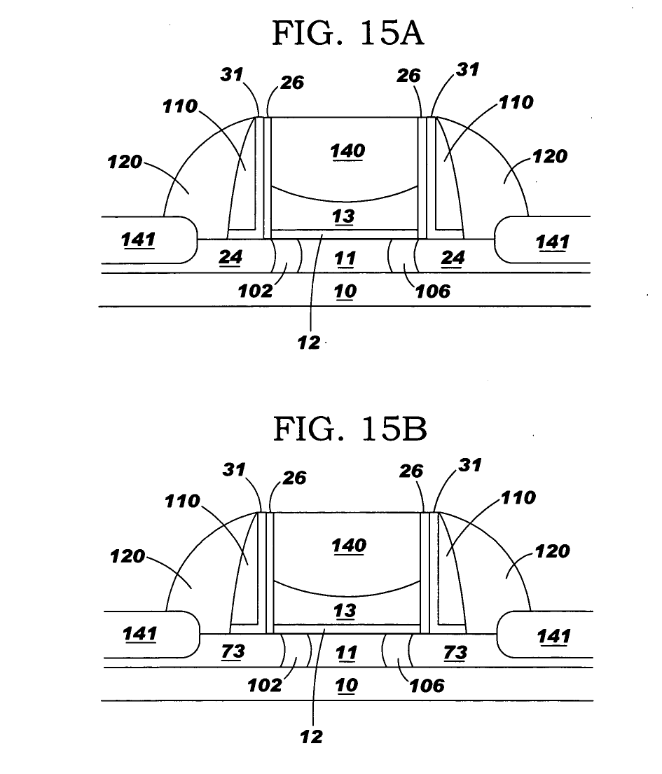

The “A” figures represent an N-type device while the “B” Figures represent a P-type device. Further, to simplify the drawings, only one half of each of the structures (e.g., the left half) has been illustrated in FIGS. 1A-14B. The right half of each structure is the mirror image of the left half illustrated. FIGS. 15A and 15B illustrate complete (both the left and right halfs) transistor structures. In one embodiment, the invention contemplates the N-type and P-type devices being manufactured simultaneously on the same substrate or chip. Therefore, the various “A” and “B” figures represent the same processing step in the manufacturing process.

In FIGS. 1A and 1B, a laminated structure has been formed by sequentially depositing/forming various layers of material. These layers can be deposited/formed using any well-known deposition/formation process including chemical vapor deposition (CVD), liquid phase deposition (LPD), vapor phase deposition (VPD), sputtering, oxidation growth, epitaxial growth, etc. The first layers comprise an insulator (oxide) 10 and a silicon layer 11.

The oxide 10 isolates the silicon layer 11 from electrical contact with the underlying substrate (not shown). This type of structure is known as Silicon-On-Insulator (SOI) structure because the silicon 11 is over an insulator (in this case oxide 10). In such a structure, the oxide 10 is referred to as a buried oxide (BOX). The buried oxide 10 isolates the transistor from any underlying structures. The invention described below shows its particular application to such SOI structures. However, this invention is applied to both SOI and bulk Si substrate technologies with equal applicability and importance.

Item 12 represents the gate oxide; item 13 represents the gate conductor. The gate conductor 13 can be any conductive material such as a metal, alloy, conductive oxide, polysilicon, etc. The thickness of the gate conductor layer 13 determines the final height of the gate conductor.

Items 14-16 are sacrificial insulator materials that will be removed from the final structure and are utilized only during the manufacturing process. In this example, item 14 is an oxide, item 15 is a nitride, and item 16 is a hard insulator material (e.g., tetraethylorthosilicate (TEOS)); however any number and type of sacrificial materials could be utilized depending upon the specific needs of the designer when creating the device being manufactured in association with disposable and final spacer materials and corresponding etch selectivity. Items 14-16 artificially increase the height of the gate during the following processing steps. This allows the height of the gate to be reduced without suffering detrimental side effects such as those discussed above. The preferable ratio of the height of the gate conductor to the sacrificial layers is determined by various design elements such as silicide thickness, target spacer width, RSD thickness, and source/drain/halo implantation energies for the substrate type, as well as the gate stack RIE process for the target gate length of the technology.

In FIGS. 2A and 2B, the upper layers (layers 12-16) are patterned into gate stacks (one half of which is illustrated in each of the drawings) using, for example, etching processes such as reactive ion etching (RIE). An additional oxide 26 is grown over the gate stack for protection of gate oxide, gate poly, and extension regions during subsequent processing. For the N-type device shown in Figure 2A, an extension implant 22 (e.g., arsenic, etc.) is made to create the N-type extension 24 within the silicon layer 11. As explained in greater detail below, implanting arsenic at this stage will not result in undesirable impurity diffusion because arsenic diffuses relatively slowly compared to other impurities. The P-type devices shown in FIG. 2B are protected during this processing using a mask (not shown) to avoid implanting the N-type extension impurity. Further, the gate stack aligns the extension implant 24 precisely with the edge of the gate.

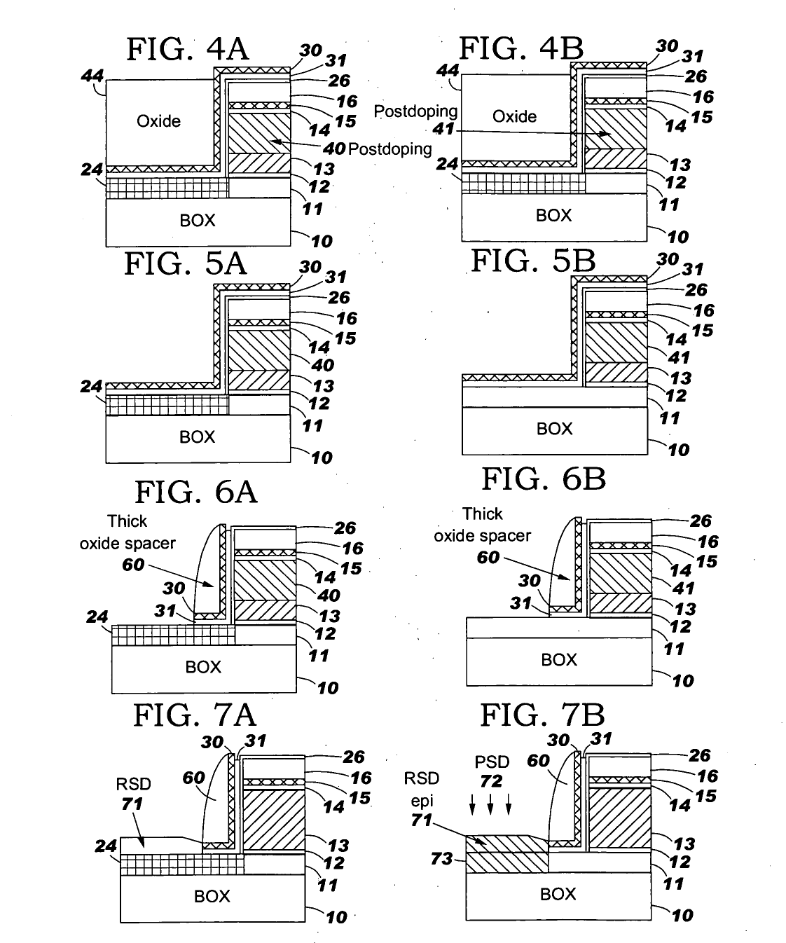

In FIGS. 3A and 3B, protective caps 30, 31 are formed over the structure. The cap 31 comprises a Low Temperature Oxidation (LTO) cap while material 30 comprises, for example, a nitride layer formed in a rapid thermal chemical vapor deposition (RTCVD) process. In FIG. 4, a protective oxide 44 is formed over the structure. The oxide 44 is reduced in height using a chemical mechanical polishing (CMP) in an over etching process so that the oxide does not block the top of the gate stack. Then, separate impurities are implanted in separate gate post doping processing steps for the N-type and P-type devices. More specifically, the P-type device shown in FIG. 4B is protected using a mask (not shown) while an N-type gate implant (phosphorus or arsenic) 40 is made into the gate conductor 13, followed by an optional rapid thermal anneal (RTA). Subsequently, the N-type device shown in Figure 4A is protected, again using a mask (not shown) while a P-type gate implant (boron, BF2, etc.) 41 can be made into the gate conductor 13. As an alternative to the above gate postdoping scheme, one can also predope the gate by low energy implantation of dopants immediately after depositing the poly layer 13 of reduced height, before forming the sacrificial buffer layers 14, 15, and 16.

The additional thickness provided by the sacrificial layers 14-16 allows a sufficiently high-energy—implantation (e.g. boron higher than 5 keV, arsenic higher than 10 keV, and phosphorus higher than 8 keV) to be utilized for doping not only the gate but also the source, drain, and halo regions without impurity penetration through the gate oxide 12 into the channel region of silicon 11. In other words, the conventional implant process that is self-aligned with the gate stack can be utilized with the invention because the thickness of the buffer layer causes the impurities to be implanted to the same depth within the inventive gate structure, as they would be with conventional taller gate structures. Therefore, the invention allows well-known implantation technology to be utilized, thereby simplifying and reducing the cost of manufacturing the device. Further, the invention allows this conventional processing, yet eliminates the risk of unwanted impurity penetration by providing the sacrificial layers 14-16 above the actual gate conductor 13.

Then, as shown FIGS. 5A and 5B, the protective oxide 44 is removed by, for example, a wet etch using a buffered HF solution. Then, a spacer material is deposited and formed into a temporary spacer 60 in, for example, an anisotropic dry etch or RIE. The RIE process and additional etch (as in conventional composite spacer formation technology) also removes the portions of the nitride 30 over the oxide cap 31 on the gate that are not protected by the spacers 60, as shown in FIGS. 6A and 6B.

In FIGS. 7A and 7B, the raised source and drain regions 71 are grown in an epitaxial process. Due to the sacrificial buffer layers 14-16, the unnecessary epi overgrowth on the poly gate is prevented. Furthermore, the epi process, as explained above, exposes the structure to a thermal cycles at temperatures ranging from 750C to 900C, approximately, for more than several minutes. This thermal process diffuses the N-type and P-type impurities 40, 41 throughout the gate conductor 13.

As also shown and FIGS. 7A and 7B, the N-type devices are protected by a mask (not shown) and the P-type devices are subjected to a P-type implantation process 72 (e.g., Boron, BF₂, etc.) which dopes the raised source and drain regions 71 of the P-type transistor and also creates a P-type source and drain 73 within the silicon 11. As mentioned previously, since this implant is performed after the raised source and drain regions are grown, it avoids the high thermal cycles associated with the epitaxial process of growing the raised source and drain regions. Therefore, by performing this implant and the other subsequent implants after the high thermal epitaxial raised source/drain process, the invention eliminates the deleterious transient enhanced diffusion of boron during the epi growth.

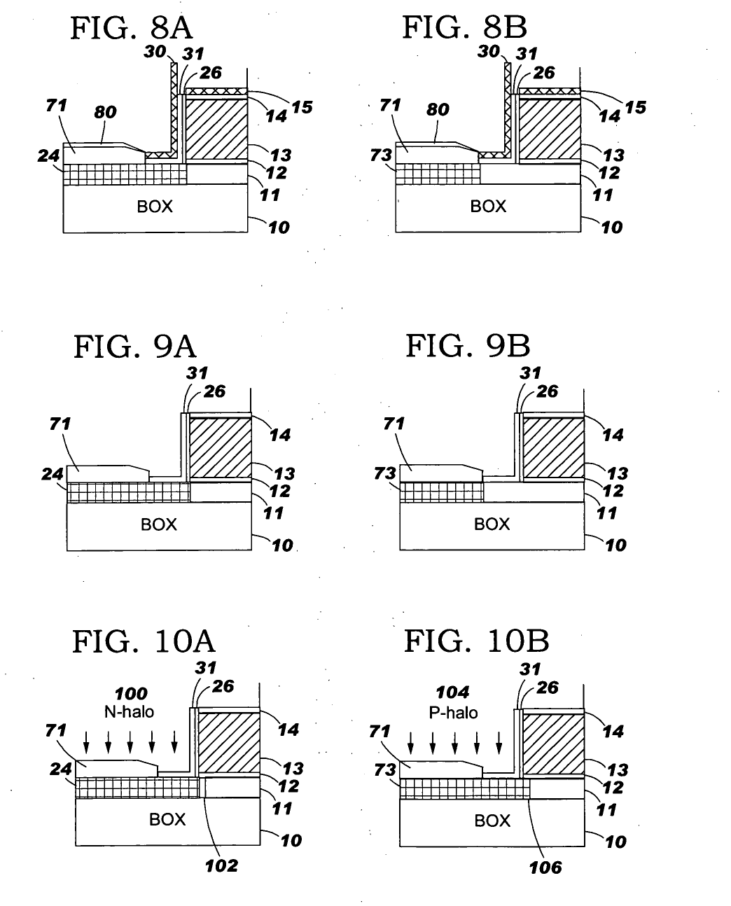

In FIGS. 8A and 8B, the oxide spacer and top oxide 16, as well as portions of the oxide 26 and cap 31 are removed in an etching process. At this stage, the invention achieves the poly gate height reduction. In addition, the invention optionally grows a thin oxide 80 (shown only in FIGS. 8A and 8B) at a low temperature to protect the surfaces of the doped raised source drain regions 71. This optional process also helps regrow any oxide 26 which may have been removed from the corners of the gate conductor 13 during the etch that removed the spacers 60.

In FIGS. 9A and 9B, the nitride liners 30 are removed in an etching process. Next, as shown in FIGS. 10A and 10B, the -N-halo for NFET 100 (boron, BF 2) and P-halo for PFET 104 (arsenic, phosphorus) implants are made to create halo implant regions 102, 106. These halo implants are performed separately in processes where one type of transistor is protected while the other type of transistor receives the appropriate implant, and vice versa. As explained above, since the halo implants are made after the high thermal budget epitaxial raised source/drain form ation process, the deleterious effect of transient enhanced diffusion of boron N-halo is bypassed with the invention.

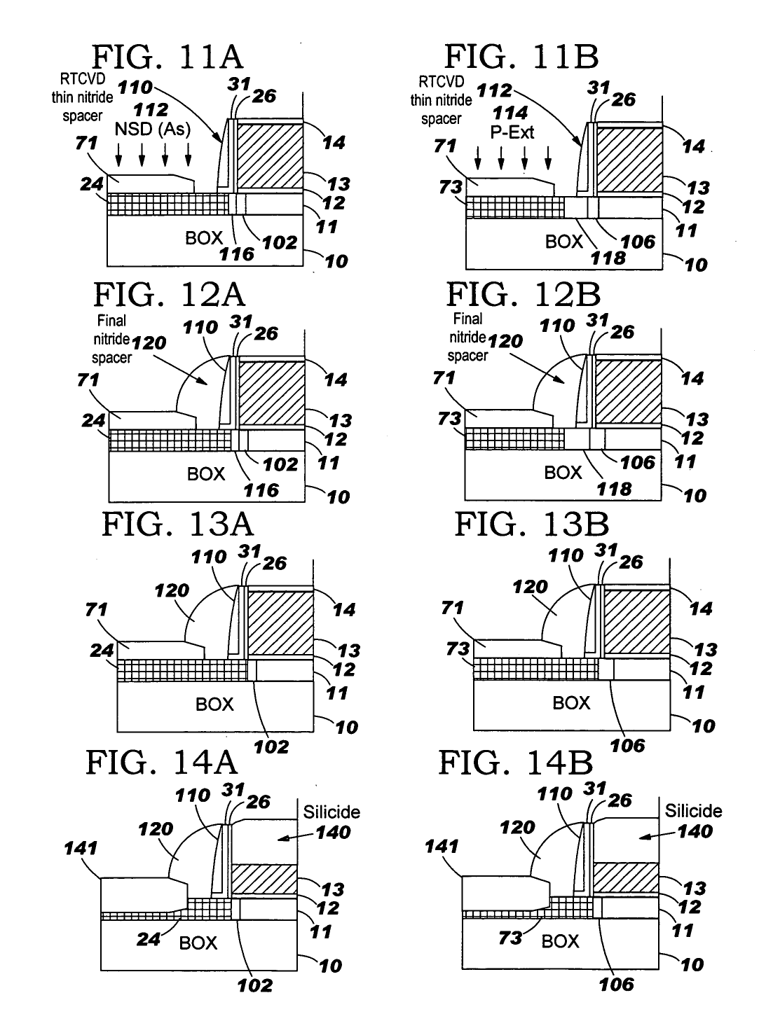

In FIGS. 11A and 11B, a permanent nitride spacer 110 is formed using well-known deposition and etching/shaping techniques (e.g., RTCVD). Subsequently, an N-type source/drain implant (arsenic or phosphorus) is performed while the P-type devices are protected with a mask; and a P-type extension implant 114 (boron, BF2, etc.) is performed while the N-type devices are protected with a different mask. These implants introduces doping within the raised sources and drains 71, 24 and 71, 73 and also dope the portions 116, 118 of the associated extension regions.

In FIGS. 12A and 12B, a final permanent spacer 120 (nitride) is deposited and shaped using conventional techniques. While the permanent spacer 110 is smaller than the sacrificial spacer 60, the final spacer 120 is larger than both the permanent spacer 110 and the sacrificial spacer 60. Indeed, as shown and FIGS. 12A and 12B, the final permanent spacer 120 extends to cover the corners of the raised source and drain regions 71 which may have facets.

In FIGS. 13A and 13B, a high temperature rapid thermal anneal (RTA) is applied to activate the various dopants. Therefore, the dopants implanted so far are redistributed throughout the raised source and drain regions 71 as well as the extensions 24, 73, and throughout the poly gates 13. Note that this is the first high temperature thermal cycle which the dopants in the halos 102, 106 are subjected to. As mentioned above, because the majority of the boron and other fast-moving impurities are implanted after the high thermal budget process of forming the raised source and drain regions, these impurities only receive the minimum necessary thermal budget in the remaining processing (such as the rapid thermal anneal shown in FIGS. 13A and 13B). Once again, this allows the invention to prevent unnecessary transient enhanced diffusion problems. FIG. 11A shows NSD (NFET source/drain) as using the thin nitride spacer, whereas FIG. 7B shows PSD (PFET source/drain) implantation aligned with the larger disposable spacer. As a different embodiment, these implants can be done after the large final spacer formation (e.g., see FIGS. 13A and 13B).

FIGS. 14A and 14B illustrate the structure after a conventional silicide process has created silicide regions 140, 141 above the gate conductor 13 and where the raised source and drain regions 71 previously existed. FIGS. 15A and 15B show essentially the same structures as shown and 14A and 14B illustrating both sides of the structure instead of the one half views shown in FIGS. 14A and 14B.

Therefore, as shown above, the invention resolves the problems associated with gate height reduction by providing a sacrificial layer above the gate during processing. By reducing the poly height without incurring the various conventional problems, this invention accomplishes the ultimate goal of reducing the parasitic capacitance between the silicided gate electrode and the source/drain electrodes and their electrically connected metallization/contact structures. The reduced height of the poly gate in combination with raised source/drains also achieves higher drive currents without the expense of increasing the gate-to-source/drain parasitic capacitance and degrading the overall circuit performance. The buffer layer on top of the gate polysilicon artificially increases the gate height during processing, thereby making it possible to use sufficiently high energy implantation of the PFET source/drain and gate, without incurring the conventional boron penetration problem. Additional variation of this embodiment may include implantation of NFET source/drain and gate using phosphorus or arsenic at a sufficiently high energy before the removal of the buffer layer 16 in FIG. 7A, instead of after the removal in FIG. 11A.

The artificial increase in gate height achieved with the sacrificial layer at the top of the gate stack allows the formation of larger disposable spacers. Without the sacrificial buffer layers 14-16, a simply reduced gate height would make it difficult to form a disposable spacer large enough to separate the raised source/drain regions from the gate sidewall in FIGS. 6A and 6B. The invention uses a two-step spacer formation process for spacer width modulation. With the larger spacers, the invention also avoids the dopant encroachment and suicide bridging problems that can occur when reduced gate heights decrease the size of the spacers.

To avoid the boron diffusion problem discussed above, the invention implants boron for N-halo, P-extension and P-type source and drains after the raised source/drains are formed. This process still allows slow diffusing dopants, such as arsenic, to be introduced before the RSD processing. Additionally, the width of the final spacer is made relatively larger for PFETs than for NFETs, in order to give more room for boron diffusion in the PFET sources and drains.

As an extension of the preferred embodiment, another embodiment of this invention is described as follows. In FIGS. 6A-6B, a nitride disposable spacer is formed instead of an oxide spacer on the nitride liner. In this structure, therefore, the disposable spacer material is different from the sacrificial buffer material (oxide in this case) on top of the gate. After the epi growth for RSD formation in FIG. 8A-8B, (and an optional deep source/drain implantation) a thicker oxide is grown on the surface of RSD layer 71 so that the thickness of this RSD surface oxide is approximately equal to the thickness of the buffer oxide layer 16. Afterwards, only the nitride disposable spacer is removed selectively by hot phosphoric acid, without etching away the oxide buffer layer 16 and the RSD surface oxide layer. Then, a halo implantation is performed at an energy and dose high enough to control the short channel rolloff for both SOI and bulk Si CMOS technologies. Due to the buffer layer 16 on the gate poly in this embodiment, this halo implant at a relatively high energy does not penetrate through the gate poly into the channel, which must be avoided. Source/drain extension implantation is also performed at this stage. Optionally, one can use a thin permanent spacer 110 before or after the halo and extension implantation, as with the preferred embodiment FIG. 11A-11B. In this embodiment, however, the thin spacer material should be oxide instead of nitride. Then, formed is a final large oxide spacer filling the spacing between the RSD layer and the sidewall of the gate stack, using RIE which also anisotropically etches off the buffer layer 16 and the RSD surface oxide layer by overetch. Alternative, the filling of the spacing can be performed by isotropic etchback of the oxide deposited to a sufficient thickness to cover both gate poly buffer and RSD layers. As a result, this step achieves reduced poly height in a structure similar to FIGS. 13A-13B, with much more reduction in poly height. Additional implantation for source/drain electrode and the gate poly is performed at a low energy at this stage to avoid dopant penetration into the channel. A final RTA activates all the dopants, and silicidation forms the final source/drain and gate electrodes with reduced gate poly and RSD. Therefore, this secondary embodiment also reduces the parasitic gate-to-source/drain capacitance by reducing the poly height, maximizes drive currents by forming the RSD layer, and achieves short channel rolloff by optimal halo/extension implantation in the channel with sufficiently high energies without causing dopant penetration through the poly gate.

The artificial increase in gate height achieved with the sacrificial layer at the top of the gate stack allows the formation of larger disposable spacers. The invention uses a two-step spacer formation process for spacer width modulation (sacrificial and permanent spacers). With the larger spacers, the invention also avoids the dopant encroachment and silicide bridging problems that can occur when the reduced gate height limits and decreases the achievable size of the spacers.

While the invention has been described in terms of preferred embodiments, those skilled in the art will recognize that the invention can be practiced with modification within the spirit and scope of the appended claims.

1. A method of forming an integrated circuit transistor having a reduced gate height, said method comprising:
forming a laminated structure having a substrate, a gate conductor above said substrate, and at least one sacrificial layer above said gate conductor;
patterning said laminated structure into at least one gate stack extending from said substrate;
forming spacers adjacent said gate stack;
doping regions of said substrate not protected by said spacers to form source and drain regions adjacent said gate stack; and
removing said spacers and said sacrificial layer.

2. The method in claim 1, wherein the height of said gate conductor is smaller than a gate height associated with the spacing of the source and drain regions created by said spacers.

3. The method in claim 1, wherein the size of said spacers is controlled by the combined height of said gate conductor and said sacrificial layer, such that said spacers provide larger spacing for said combined height when compared to the height of said gate conductor alone.

4. The method in claim 3, wherein said larger spacing positions said source and drain regions further from said gate conductor when compared to source and drain regions formed with spacers formed only to said height of said gate conductor.

5. The method in claim 1, wherein said sacrificial layer above said gate conductor is formed in a process comprising:
forming a sacrificial oxide layer above said gate conductor, and
forming additional sacrificial layers above said oxide layer

6. The method in claim 5, wherein said sacrificial oxide layer protects said gate conductor.

7. The method in claim 1, wherein said laminated structure includes a silicon layer below said gate conductor,
wherein said method further comprises doping source/drain electrodes and said gate conductor together in a self-aligned implantation after said patterning process,
wherein the combined height of said gate conductor and said sacrificial layer prevents said impurity from reaching said silicon layer, and
whereas, without said sacrificial layer, said doping process would implant an impurity through said gate conductor and gate dielectric layer to said silicon layer.

8. The method in claim 1, wherein said laminated structure includes a silicon layer below said gate conductor,
wherein said method further comprises a first doping process of doping source/drain electrodes and said gate conductor together in a self-aligned implantation after said patterning process,
wherein said method further comprises a second doping process of doping halo regions below said gate conductor in a self-aligned implantation with an impurity of an opposite polarity to that used in said first doping process after said first doping process,
wherein the combined height of said gate conductor and said sacrificial layer prevents impurities from reaching said silicon layer, and
whereas, without said sacrificial layer, said doping processes would implant impurities through said gate conductor and gate dielectric layer to said silicon layer.

9. A method of forming an integrated circuit transistor having a reduced gate height, said method comprising:
forming a laminated structure having a substrate, a gate conductor above said substrate, and at least one sacrificial layer above said gate conductor;
patterning said laminated structure into at least one gate stack extending from said substrate;
forming spacers adjacent said gate stack;
epitaxially growing raised source and drain regions on said substrate adjacent said gate stack;
implanting impurities into said raised source and drain regions and into said substrate; and
removing said spacers and said sacrificial layer.

10. The method in claim 9, wherein the size of said spacers is controlled by the combined height of said gate conductor and said sacrificial layer, such that said spacers provide larger spacing for said combined height when compared to the height of said gate conductor alone.

11. The method in claim 10, wherein said larger spacing positions said raised source and drain regions further from said gate conductor when compared to raised source and drain regions formed with spacers formed only to said height of said gate conductor.

12. The method in claim 9, wherein said sacrificial layer above said gate conductor is formed in a process comprising:
forming a sacrificial oxide layer above said gate conductor, and
forming additional sacrificial layers above said oxide layer,
wherein said sacrificial oxide layer protects said gate conductor.

13. The method in claim 9, wherein said laminated structure includes a silicon layer below said gate conductor,
wherein said method further comprises doping said source/drain electrodes and said gate conductor together in a self-aligned implantation after said patterning process,
wherein the combined height of said gate conductor and said sacrificial layer prevents said impurity from reaching said silicon layer, and
whereas, without said sacrificial layer, said doping process would implant an impurity through said gate conductor and gate dielectric layer to said silicon layer.

14. The method in claim 9, wherein said laminated structure includes a silicon layer below said gate conductor,
wherein said method further comprises a first doping process of doping source/drain electrodes and said gate conductor together in a self-aligned implantation after said patterning process,
wherein said method further comprises a second doping process of doping halo regions below said gate conductor in a self-aligned implantation with an impurity of an opposite polarity to that used in said first doping process after said first doping process,
wherein the combined height of said gate conductor and said sacrificial layer prevents impurities from reaching said silicon layer, and
whereas, without said sacrificial layer, said doping processes would implant impurities through said gate conductor and gate dielectric layer to said silicon layer.

15. The method in claim 9, wherein by implanting said impurities after said epitaxially growing process, said impurities avoid being subjected to the thermal budget of said epitaxially growing process.

16. A method of forming an integrated circuit transistor having a reduced gate height, said method comprising:
forming a laminated structure having a substrate, a gate conductor above said substrate, and at least one sacrificial layer above said gate conductor;
patterning said laminated structure into at least one gate stack extending from said substrate;
epitaxially growing raised source and drain regions on said substrate adjacent said gate stack, wherein said process of epitaxially growing said raised source and drain regions is performed in the absence of doping impurities;
implanting impurities into said raised source and drain regions and into said substrate,
removing said spacers and said sacrificial layer.

17. The method in claim 16, wherein the height of said gate conductor is smaller than a gate height associated with the spacing of the source and drain regions created by said spacers.

18. The method in claim 16, wherein the size of said spacers is controlled by the combined height of said gate conductor and said sacrificial layer, such that said spacers provide larger spacing for said combined height when compared to the height of said gate conductor alone.

19. The method in claim 18, wherein said larger spacing positions said source and drain regions further from said gate conductor when compared to source and drain regions formed with spacers formed only to said height of said gate conductor.

20. The method in claim 16, wherein said sacrificial layer above said gate conductor is formed in a process comprising:
forming a sacrificial oxide layer above said gate conductor, and
forming additional sacrificial layers above said oxide layer.

21. The method in claim 20, wherein said sacrificial oxide layer protects said gate conductor.

22. The method in claim 16, wherein said laminated structure includes a silicon layer below said gate conductor,
wherein said method further comprises doping said source/drain electrodes and said gate conductor together in a self-aligned implantation after said patterning process,
wherein the combined height of said gate conductor and said sacrificial layer prevents said impurity from reaching said silicon layer, and
whereas, without said sacrificial layer, said doping process would implant an impurity through said gate conductor and gate dielectric layer to said silicon layer.

23. The method in claim 16, wherein said laminated structure includes a silicon layer below said gate conductor,
wherein said method further comprises a first doping process of doping source/drain electrodes and said gate conductor together in a self-aligned implantation after said patterning process,
wherein said method further comprises a second doping process of doping halo regions below said gate conductor in a self-aligned implantation with an impurity of an opposite polarity that used in said first doping process after said first doping process,
wherein the combined height of said gate conductor and said sacrificial layer prevents impurities from reaching said silicon layer, and
whereas, without said sacrificial layer, said doping processes would implant impurities through said gate conductor and gate dielectric layer to said silicon layer.

24. A method of producing an integrated circuit transistor comprising:
forming a laminated stack deposition, wherein said laminated stack deposition is formed in a process comprising:
forming a silicon layer over a substrate layer;
forming a gate oxide on said silicon layer;
forming a gate conductor on said gate oxide; and
forming of least one sacrificial material above said gate conductor,
patterning said gate oxide, gate conductor, and said sacrificial material into at least one gate stack;
forming temporary spacers adjacent said gate stack;
epitaxially growing raised source and drain regions above said substrate layer adjacent said temporary spacers, such that said temporary spacers separate said raised source and drain regions from said gate stack;
growing an additional dielectric layer on said raised source and drain regions;
removing said temporary spacers without removing said sacrificial material;
performing a halo implant in said raised source and drain regions and in exposed regions of said silicon layer;
forming a permanent spacer adjacent said gate stack, wherein said permanent spacer is thinner than said temporary spacer;
implanting impurities into said raised source and drain regions and exposed regions of said silicon;
forming a final spacer filling said exposed regions of said silicon between said permanent spacer and said raised source and drain regions;
implanting additional impurities into said raised source and drain regions and exposed regions of said silicon;
annealing to activate all impurities;
etching back said additional dielectric layer on said raised source and drain regions; and
saliciding both said gate conductor and said raised source and drain regions.

25. The method in claim 24, wherein said process of epitaxially growing said raised source and drain regions is performed in the absence of doping impurities.

26. The method in claim 24, wherein said removing of said sacrificial layer reduces the height of said gate conductor relative to the gate height associated with the spacing of the source and drain regions created by said spacers.

27. The method in claim 24, wherein said forming of said sacrificial material above said gate conductor further comprises forming a sacrificial oxide layer above said gate conductor, forming a sacrificial nitride layer above said oxide layer and forming a sacrificial hard insulator material above said nitride layer.

28. The method in claim 31, wherein said sacrificial oxide layer protects said gate conductor.
